(19) United States
(12) Patent Application Publication
(10) Pub. No.: US 2017/0347460 A1
(43) Pub. Date: Nov. 30, 2017

(54) Stretchable Electrically Conductive Layer Formation By Aerosol Jet Printing On Flexible Substrate

(71) Applicant: Duke University, Durham, NC (US)

(72) Inventors: Changyong Cao, Durham, NC (US); Yihao Zhou, Durham, NC (US); Jeffrey T. Glass, Durham, NC (US); Aaron D. Franklin, Cary, NC (US)

(21) Appl. No.: 15/230,588

(22) Filed: Aug. 8, 2016

Related U.S. Application Data
(60) Provisional application No. 62/342,246, filed on May 27, 2016.
(60) Provisional application No. 62/347,255, filed on Jun. 8, 2016.

(51) Int. Cl. H05K 3/12; H05K 1/02; H05K 1/09; H05K 3/00

(52) U.S. Cl. CPC H05K 3/125; H05K 3/0014; H05K 3/1283; H05K 1/0283; H05K 1/097; H05K 2201/0323

(57) ABSTRACT

Methods of forming an electrically conductive layer on a flexible substrate, such as a stretchable electrode, by aerosol jet printing on the flexible substrate while the substrate is strained. In general, a stretchable substrate is initially deformed so that a first surface thereof is under tension. While the substrate is in the strained state, an ink is aerosol jet printed onto the first surface. The ink includes carbon nanotubes, and advantageously other materials such as reduced graphene oxide. Further, while the substrate is still in the strained state, the ink is cured after its application to the substrate. Thereafter, the strain is decreased so that the stretchable substrate contracts, self-organizing into a configuration wherein the substrate's first surface, with the cured ink thereon, has a wrinkled profile. The flexible substrate can then be mechanically expanded and contracted, advantageously repeatedly, with the ink layer maintaining electrical conductivity.

This application claims the benefit of U.S. Provisional Application No. 62/342,246, filed 27 May 2016 and entitled “Stretchable Electrically Conductive Layer Formation By Aerosol Jet Printing On Flexible Substrate,” and U.S. Provisional Application No. 62/347,255, filed 8 Jun. 2016 and entitled “Hybrid Carbon Nanotube Graphene Compositions for Stretchable High Performance Electronic Materials,” the entire disclosures of both which are incorporated herein by reference.

### BACKGROUND

The present invention relates to aerosol jet printing, and particularly to aerosol jet printing of nanomaterial ink on a substrate to form an electrically conductive layer on a flexible substrate, such as might be used as a stretchable electrode.

Printable electronics are receiving increased interest, in part because such electronics may be useful in a variety of applications. These printable electronics, like conventional electronics, require some form of power to operate, such as a battery or capacitor, etc. However, providing integrated and printable power sources has proven problematic. In particular, it has proven difficult to directly print “supercapacitors” with high performance (e.g., high energy density and/or high power density and/or quick charge-discharge rates) and with suitable stretchability. As such, there remains a need for alternative approaches to fabricating printable electronics, advantageously approaches that provide good manufacturability, are simple, are low-cost, and/or are environmentally friendly.

### SUMMARY

Described below are one or more embodiments of methods of forming an electrically conductive layer on a flexible substrate by aerosol jet printing on a flexible substrate while the substrate is strained. In general, a stretchable substrate is initially deformed so that a first surface thereof is under tension. While the substrate is deformed to a strained state, with the first surface thereof under tension, an ink is aerosol jet printed onto the first surface, with ink comprising carbon nanotubes, and advantageously other materials such as reduced graphene oxide. While the substrate is still in the strained state, the ink is cured after its application to the substrate. Thereafter, the strain is decreased/relaxed so that the stretchable substrate contracts, self-organizing into a configuration wherein the substrate's first surface, with the cured ink thereon, has a wrinkled profile. The flexible substrate with the electrically conductive layer thereon formed by these inventive processes may be used as an electrode, or for other uses.

In one or more embodiments, the present invention provides a method of forming an electrically conductive layer on a flexible substrate. The method comprises deforming a stretchable substrate so that a first surface thereof is strained in tension by at least 10% (or to another desired strain level). While the first surface is strained by at least 10%, an ink is aerosol jet printed onto the first surface of the substrate, with the ink comprising carbon nanotubes. Also, while the first surface is strained by at least 10%, the ink is cured after its application to the substrate. Thereafter, the tension is decreased so that the substrate relaxes to self-organize into a configuration wherein the first surface of the substrate having cured ink thereon has a wrinkled surface profile. The aerosol jet printing may comprise aerosol jet printing while the substrate is receiving heat from at least one heat source, which may, for example, be a radiant heat source. The aerosol jet printing may also or alternatively comprise aerosol jet printing while a second surface of the substrate, which faces opposite the first surface, is spaced from any support at a location directly opposite a print nozzle used for the aerosol jet printing. The aerosol jet printing may also or alternatively comprise supplying ink from a nozzle directed at the first surface, with no intervening structure between the nozzle and the first surface; and wherein the nozzle is spaced from the first surface during the aerosol jet printing. The ink, prior to curing, may comprise methanol or other solvents. During the aerosol jet printing the ink on the first surface of the substrate, the first surface of the substrate may be in tension along a first axis and along a second axis transverse to the first axis. For such an arrangement, the releasing of the tension may comprise reducing tension along the first axis while maintaining tension along the second axis, and thereafter, reducing tension along the second axis. Alternatively, for such an arrangement, the releasing the tension may comprise substantially simultaneously releasing the tension along both the first axis and the second axis. For any of the above embodiments, the substrate may be formed such that it may thereafter be subjected to repeated cycles of mechanical tension and relaxation, with the cured ink maintaining electrical conductivity throughout the mechanical tension and relaxation. Similarly, for any of the above embodiments, the substrate may be formed such that it may thereafter be subjected to mechanical stress such that the first surface is in tension, and thereafter the mechanical stress is decreased, with the cured ink maintaining electrical conductivity throughout the mechanical stressing and releasing. Note that the aerosol jet printing and the curing may, but are not required to, overlap in time. For any of the above embodiments, the decreasing the tension may be partially, or fully, releasing the applied tension.

In other embodiments, the present invention provides a method of printing a stretchable electrode on a flexible substrate. The method may start with deforming an electrode substrate so that a first surface thereof is strained in tension by at least 10%. Then, while the electrode substrate is deformed so that the first surface thereof is strained in tension by at least 10%: a) an ink is aerosol jet printed directly onto a first surface of the electrode substrate while the electrode substrate is heated, and b) the ink is cured after its application to the substrate. The ink comprises carbon nanotubes and graphene oxide, optionally reduced graphene oxide. A printhead directing the ink to the first surface moves relative to the substrate during the printing. Thereafter, the tension is decreased so that the electrode substrate self organizes into a configuration wherein the first surface of the electrode substrate having cured ink thereon has a wrinkled surface profile. The heating of the electrode substrate is discontinued. In some of these embodiments, the aerosol jet printing comprises aerosol jet printing while the electrode substrate is receiving heat from at least one heat source, which may, for example, be a radiant heat source. In some of these embodiments, the ink, prior to curing, comprises methanol or other solvent. In some of these embodiments, during the aerosol jet printing the ink on the first surface of the substrate, the first surface of the substrate is in tension along a first axis and along a second axis transverse to the first axis.

The various aspects of the devices and methods discussed herein may be used alone or in any combination. Further, the present invention is not limited to the above features and advantages. Indeed, those skilled in the art will recognize additional features and advantages upon reading the following detailed description, and upon viewing the accompanying drawings.

### BRIEF DESCRIPTION OF THE DRAWINGS

FIG. 1 shows a simplified process flow chart according to one or more embodiments.

FIG. 2 shows another simplified process flow chart according to one or more embodiments.

FIG. 3 shows a perspective view tension application assembly with a substrate stretched and clamped.

FIG. 4 shows a simplified schematic of an aerosol printing apparatus.

FIG. 5 shows a simplified schematic representation of a nozzle cross-section during ink deposition.

FIG. 6 shows a top view of an upper surface of a substrate having a wrinkled profile after tension decrease.

FIG. 7 shows a portion of a cross-section of the surface of FIG. 6, with the substrate in a relaxed state.

FIG. 8 shows the cross-section shown in FIG. 7, with the substrate in a partially expanded state.

### DETAILED DESCRIPTION

The present application is generally directed to methods of forming an electrically conductive layer on a flexible substrate via aerosol jet printing a nanomaterial ink and related technology. For simplicity, the flexible substrate with the electrically conductive layer, generally indicated at 100, will be discussed below generally in the context of an illustrative example of a conductive electrode. However, it should be understood that the flexible substrate with the electrically conducive layer thereon formed by the processed described herein may be used for various purposes, such as making various printable electronics (e.g., a battery or supercapacitor), electromagnetic shielding, or other uses where a flexible electrically conductive layer on a flexible substrate would be useful or desired.

As an illustrative example, a stretchable electrode 100 is formed by initially deforming a stretchable substrate 102 so that a first surface 104 thereof is under tension so as to be strained by at least 10% (or other amounts discussed below). While the substrate 102 is deformed to a strained state, with the first surface 104 thereof under tension, an ink 10 is aerosol jet printed onto the first surface 104, with ink comprising carbon nanotubes, and optionally reduced graphene oxide and/or Poly(2,3-dihydrothieno-1,4-dioxin)-poly(styrenesulfonate) (“PEDOT:PSS”). While the substrate 102 is still in the strained state, the ink 10 is cured after its application to the substrate 102. Thereafter, the strain is decreased so that the stretchable substrate contracts, self-organizing into a configuration wherein the substrate's first surface 104, with the cured ink thereon, has a wrinkled profile.

As discussed above, in one or more exemplary embodiments, the present invention relates to aerosol jet printing ink onto a stretchable substrate. Aerosol jet printing is an additive manufacturing process that sprays a focused jet of aerosolized ink onto a substrate. In general, the ink is atomized, typically with pneumatic or ultrasonic energy, to create a dense mist of ink droplets of small size (e.g., two to five microns diameter). A carrier gas flow is used to transport the aerosol mist to the deposition head or nozzle where the mist is focused by an annular ring of a sheath gas flow as it is emitted from the nozzle. When the sheath gas and aerosol pass though the nozzle, they accelerate and the aerosol becomes ‘focused’ into a tight stream of droplets flowing inside the sheath gas. The resulting high velocity particle stream is directed to the substrate, which is placed in spaced relation to the nozzle. Printing an area is achieved by moving the nozzle relative to the substrate, such as the substrate remaining stationary while the nozzle moves, or vice versa. One supplier of aerosol jet printing devices is Optomec, Inc. of Albuquerque, N. Mex. For further information see, for example, U.S. Pat. No. 7,108,894. One particular advantage of aerosol jet printing the ink directly onto the substrate for the electrode is that the manufacturing process can be simplified and more reliable compared to processes where the ink is deposited on an intermediate substrate, and then transferred from the intermediate substrate to target substrate for the electrode. Further, aerosol jet printing offers the opportunity for favorable production speeds, which reduce cost for commercialization.

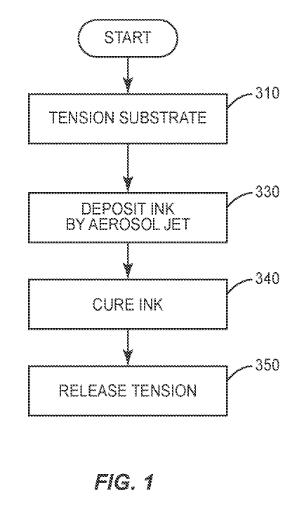

In one or more embodiments of the present invention, aerosol jet printing is utilized to print ink on a stretchable substrate while the substrate's surface is stretched so that the relevant surface of the substrate is strained in tension by at least 10%. Referring to FIG. 1, the general process flow is that a substrate 102 is deformed so that at least an upper surface 104 thereof is under tension (step 310), resulting in a strain along the upper surface 104 of at least 10% (or to another desired strain level). For example, the substrate is tensioned by being pulled in two orthogonal directions. Then, while the substrate 102 is deformed so that the upper surface 104 thereof is under tension, two process steps occur in series or parallel. First, aerosol jet printing is used to direct the ink 5 onto the upper surface 104 of the substrate 102 (step 330). Second, the ink 5, after being applied to the substrate's upper surface 104, is cured (step 340). Note that the curing (step 340) can occur immediately after the corresponding ink has been deposited (step 330), and while other portions of the substrate 102 are being printed; thus, both step 330 and step 340 can be occurring simultaneously at different locations on the substrate 102. Thereafter, the tension on the substrate is released (step 350) so that the substrate self-organizes into a configuration wherein the upper surface of the substrate having cured ink thereon has a wrinkled profile.

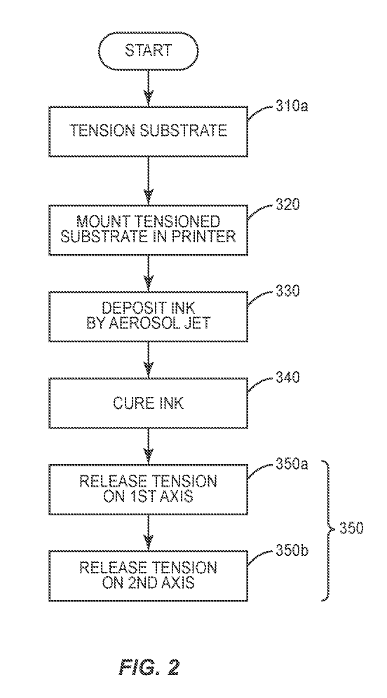

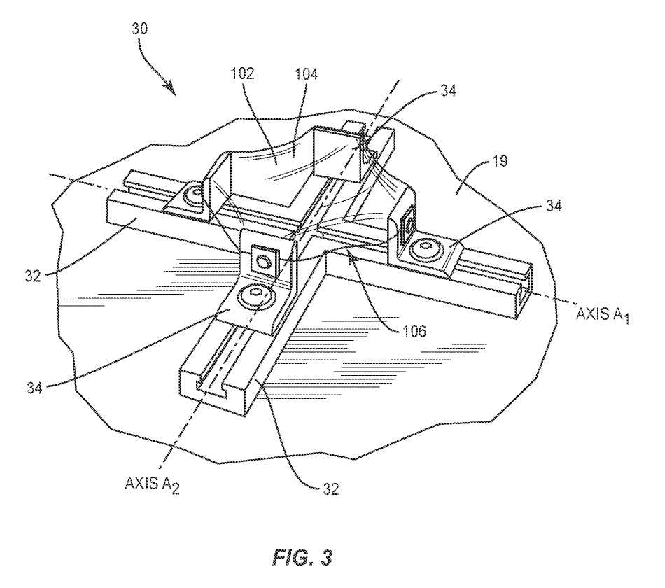

As mentioned above, the substrate 102 is tensioned during the ink deposition process (step 330). This tensioning of the substrate 102 may occur internal to the corresponding aerosol jet printing apparatus 10, but may more conveniently occur outside the aerosol jet printing apparatus 10. For example, the substrate 102 may be tensioned, sometimes referred to as stretched, via a tension assembly 30, which may have a suitable frame 32 and clamp 34 (see FIG. 3) while outside the aerosol jet printing apparatus 10 (step 310a, see FIG. 2), and then mounted to the aerosol jet printing apparatus (step 320). The frame 32 may take any suitable form, such as the simple X-shape form illustrated. Suitable clamps 34 are movably mounted to the frame 32. The clamps 34 may take any suitable form known in the clamp art, such as mechanically, pneumatically, or electrically activated clamps. The substrate 102 is stretched and held in the stretched state by the clamps 34. The amount of tensioning should result in at least 10% strain, and advantageously at least 20% strain, or at least 30% strain, or at least about 100% strain, and advantageously up to about 300% strain or more. The amount of desired pre-ink-deposition strain may be dependent on the material properties of the substrate 102 and/or the ink 5 and/or the intended end application; the amount should be sufficient to achieve a wrinkled surface profile after the tension is released/decreased, and should obviously be less than that which would lead to breakage of the substrate 102. Note that the substrate 102 may be stretched before or after being gripped by the clamps 34, particularly if the clamps 34 are moveable. The stretching of the substrate 102 may be along one axis, but is advantageously along multiple axes. For example, the substrate 102 may be tensioned by being stretched along just a first axis A1, but is advantageously tensioned by also being stretched along a second axis A2, which is transverse (for ease of illustration, shown as perpendicular) to the first axis A1. Thus, the upper surface 104 of the substrate 102 is advantageously tensioned in multiple axes A1,A2. Indeed, in some embodiments, the upper surface 104 may be tensioned in more than three or more axes, including being tensioned in a circular fashion. And, while it may be advantageous for the tension to approximately equal along the plurality of axes (e.g, A1,A2), the tension may be different along different axes, as is desired. With the substrate 102 tensioned and mounted to the frame 32 via the clamps 34, the frame 32 is mounted to the aerosol jet printing apparatus 10 (step 320), such as by being secured to the platen 19 of the aerosol jet printing apparatus 10 as discussed further below.

Note that while the main illustrative example herein uses a substrate 102 with upper and lower surfaces 104,106 that are both tensioned equally, and which is flat, during the ink deposition process (step 330), such is not required. In other embodiments, the substrate 102 could be curvedly deformed, such as being stretched over a suitable mandrel, so that the upper and lower surfaces 104,106 are not equally tensioned, and/or the substrate 102 is not flat. However, the flat configuration with equal tensions is believed advantageous, and such a configuration will be used as the illustrative embodiment unless indicated otherwise.

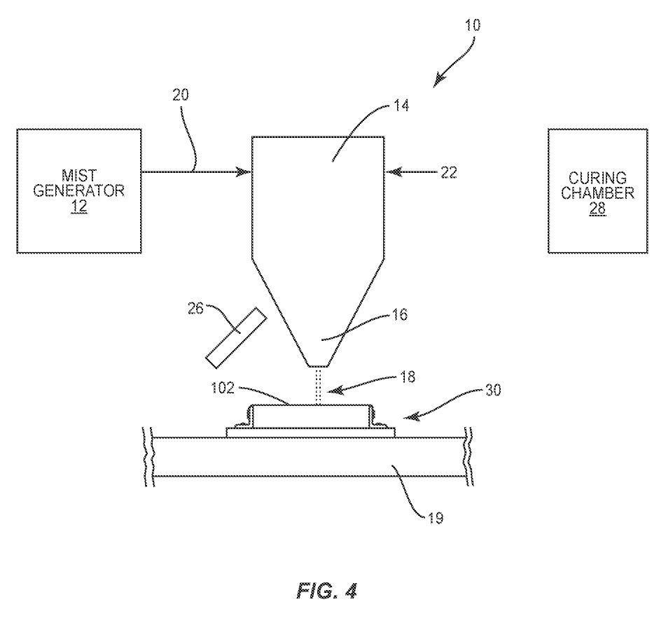

Referring to FIG. 4, a simplified aerosol jet printing apparatus is shown, and generally indicated at 10. In general, the aerosol jet printing apparatus 10 includes a mist generation unit 12, a printhead 14, and a platen 19. In general, the mist generation unit 12 supplies aerosolized ink 5 to the printhead 14, with sheath gas 22 also supplied to the printhead 14. The printhead 14 outputs the ink 5 as part of the focused jet 18 output by nozzle 16. For printing, the printhead 14 moves relative to the platen 19. The frame 32, with the clamps 34 and substrate 102 attached, is mounted to the platen 19. As such, the substrate 102 is, during the ink deposition process (step 330), held in place relative to the platen 19. Thus, when the platen 19 is displaced relative to the printhead 14, the substrate 102 is displaced relative to the printhead 14. Note that the substrate 102 is, in some embodiments, not supported from underneath. That is, the lower surface 106 of the substrate 102, at a location directly opposite to the ink deposition point X on the upper surface 104, is not abuttingly bearing against a support. Instead, the substrate 102 is suspended in spaced relation to the platen 19.

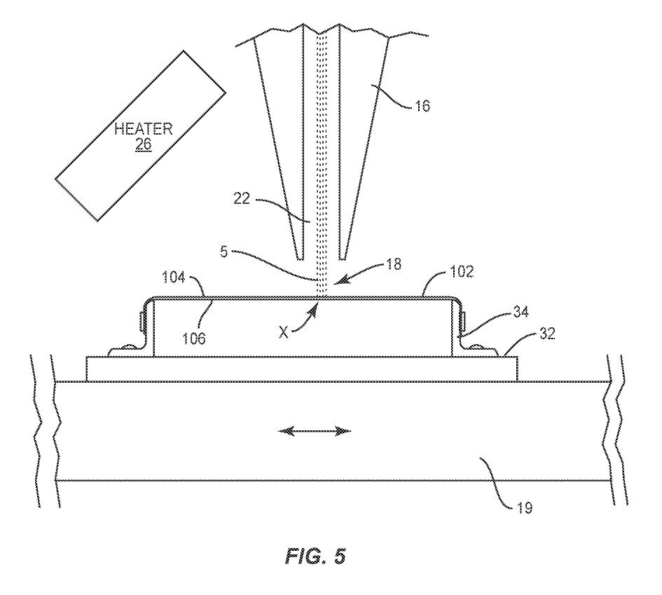

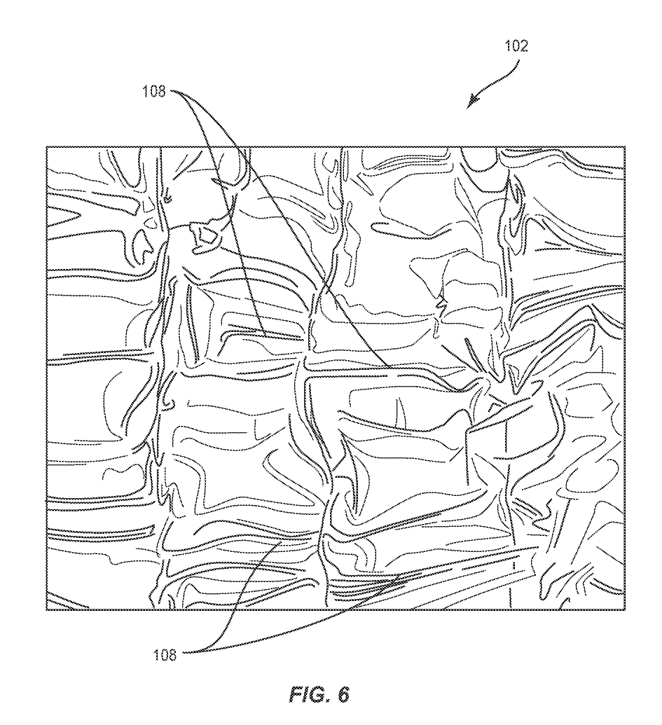

The substrate 102 is held in the tensioned state during the ink deposition process (step 330). For the ink deposition process (step 330), ink 5 is aerosolized in the mist generation unit 12, which typically uses an ultrasonic and/or pneumatic atomizer. A carrier gas is used to transport the aerosol stream 20 from the mist generation unit 12 to the printhead 14. Referring to FIG. 5, the printhead 14 has a nozzle 16 for outputting the ink 5 in a focused jet 18 toward ink deposition point X on the upper surface 104 of the substrate 102. The output jet 18 of the nozzle 16 typically has a round profile, but other profiles are possible. The jet 18 is a coaxial flow with the aerosol stream 20 in the middle and the sheath gas stream 22 annularly surrounding the aerosol stream 20. The nozzle 16 acts to focus the output flow for a tight deposition of the ink 5 at the ink deposition point X on the substrate's upper surface 104. As can be appreciated, the nozzle 16 is spaced from the substrate 102 by a suitable gap, such as about 3-5 mm. In some embodiments, the substrate 102 is advantageously heated by a suitable heat source 26 during the ink deposition process (step 330), such as a radiant heater, which may be helpful for accelerating solvent evaporation to get a uniform ink film. One example of a heater is an Optimus H-4438 Oscillating Dish Heater, available from Optimus Enterprise, Inc. of Anaheim, Calif.

The ink 5 is printed on the substrate 102 in a pattern suitable for subsequent use as a portion of an electrical component or circuit. For example, the pattern may be to cover an area of a defined size so that the resulting product can be used as an electrode 100, such as for a supercapacitor. As can be appreciated, it may be advantageous to print multiple different areas (e.g., an array of electrodes 100) during one ink deposition process (step 330). After curing and tension release, see below, the various printed areas may be singulated in any suitable way known in the art of electronics manufacture.

With the substrate 102 still held in tension, the ink 5 is cured (step 340) (sometimes called “sintering”) advantageously at a temperature above ambient, such as at about 80° C. for about twenty minutes. This curing (step 340) may take place in the aerosol jet printing apparatus 10, but advantageously occurs outside the aerosol jet printing apparatus 10. For example, once the ink deposition is completed, the frame 32, clamps 34, and the substrate 102 having ink thereon may be removed from the platen 19 and placed in a suitable curing chamber 28. Once the ink 5 is cured, the frame 32, clamps 34, and the substrate 102 having cured ink thereon may be removed from the curing chamber 28.

After curing the ink (step 340), the tension is released (step 350) from the substrate 102 so that the substrate 102 may “relax”. Note that the tension may be released along one axis at a time, such as sequentially along axis A1 (step 350a) and then along axis A2 (step 350b), etc., or may be released along all axes (e.g., axes A1, A2, . . . ) substantially simultaneously. The releasing of the tension (step 350) allows the substrate 102 to contract to a relaxed state. Note that the substrate 102 may be stretched by any suitable amount, such as 10%, 20% 30%, 100%, etc. up to about 300% or more, so that the amount of contraction is expected to be significant. Because of this, and the differing material properties of the cured ink 5 and the substrate 102, the contraction in response to the removal of the tension results in the upper surface 104 of the substrate 102 (and the cured ink thereon) self-organizing into a surface having a wrinkled profile (when in the relaxed state). By wrinkled, it is meant that surface 104 is uneven, with a plurality of folds and/or ridges in the substrate itself (and the ink) that result in a plurality of substantial local peaks and local valleys 108 in an irregular (or, less often regular or quasi-regular) array. For example, the (average) amplitude H2 of the peaks/valleys 108 may be about 10 um for a substrate of thickness of about 500 um to about 1000 um. Thus, the amplitude H2 is advantageously about 1/50th the thickness of the substrate, or more. Note that the peaks/valleys 108 may be periodic, aperiodic, or a mixture of both, and that the spacing and amplitude of the peaks/valleys are related to the thickness H1 of the cured ink layer (which is typically about 1-3 um) and the modulus of elasticity of the substrate 102. Further, note that wrinkled surface is achieved without the application of external force (e.g., manually induced folding or texturing) after the curing of the ink, but is instead achieved by the removal of external force after the curing of the ink.

Subsequent to the tension release (step 350), suitable leads (e.g., platinum wires, copper tape, etc.) may be added to the electrode 100, as may be desired. Further, the heating of the substrate is discontinued concurrently with or after the tension decreasing/releasing.

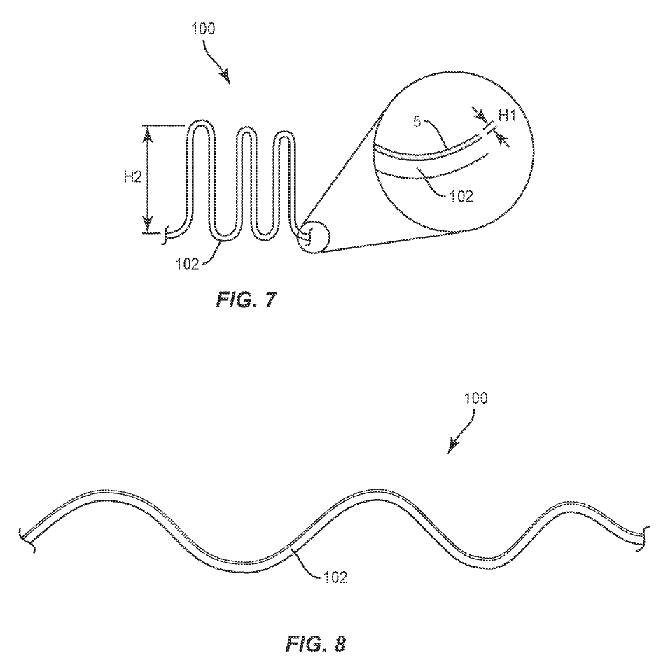

The wrinkled physical configuration of the substrate surface 104 allows the substrate 102 to be subsequently physically stretched post-production, while maintaining good adhesion between the substrate 102 and the cured ink, so that the cured ink is able to maintain electrical conductivity throughout multiple cycles of mechanical tension and relaxation. Thus, the substrate 102 may be, post production, expanded from a relaxed configuration (FIG. 7) to an expanded configuration (FIG. 8), and then released, with this stretch-relax cycle optionally repeated a plurality of times, with the cured ink maintaining electrical conductivity throughout. In addition, the wrinkled physical configuration of the surface of the substrate 102 provides an increased amount of surface area of cured ink for a given amount of projected area. In other words, increased cured ink surface area is “packed” in a small footprint. When the cured ink is forming an electrode 100, this means that the electrode 100 has increased surface area, which leads to greater effective area for the double-layer phenomenon for higher electrochemical capacitor electrical energy storage and/or effectively increased area specific capacitance.

The ink 5 used for the aerosol jet printing may be any suitable type that includes carbon nanotubes. For example, the ink may contain carbon nanotubes, graphene oxide (advantageously reduced graphene oxide (“RGO”)), and/or Poly(2,3-dihydrothieno-1,4-dioxin)-poly(styrenesulfonate) (“PEDOT:PSS”), and optionally dimethyl sulfoxide (“DMSO”). The carbon nanotubes may advantageously be P3 single-walled nanotubes (“P3-SWNT”). The RGO may be dispersed in methanol at 0.5 mg/ml. The ratio of the ink components may be P3-SWNT to RGO to PEDOT-PSS of 2:2:1 volume percent. By way of example, a carbon nanotube powder and rGO powder may be respectively dispersed in a suitable solvent (e.g., methanol) to a specific concentration, e.g., 0.5 mg/mL, and then mixed thoroughly at a desired ratio, e.g., 1:1. About twenty percent conducting polymer PEDOT:PSS may then be added. DMSO may optionally be added to the PEDOT:PSS solution prior to PEDOT:PSS solution addition, at an appropriate concentration, e.g., about 9 vol %.

The substrate 102 may be any suitable material that is stretchable at room temperature. Such materials are typically polymers, such as elastomers, but are not limited thereto. As can be appreciated, substrate 102 may advantageously be nonconductive. By way of example, the substrate 102 may be a dielectric acrylic elastomer known as VHB 4910 (1 mm thick) or VHB 4905 (0.5 mm thick), commercially available from 3M Company of Minnesota. Other exemplary substrate materials include polydimethylsiloxane (“PDMS”), polyethylene terephthalate (“PET”), and polybutyrate adipate terephthalate (“PBAT). Note that the substrate 102 should be tolerant of any materials that may contact the electrode (e.g., any electrolyte) and the expected environmental conditions (e.g., air, moisture).

The ink deposition process (step 330) may use any suitable aerosol jet printing apparatus known in the aerosol jet printing art. By way of example, the aerosol jet printing apparatus 10 may be a model AJ-300, available from Optomec, Inc. of Albuquerque, N. Mex. For such a machine, the ink deposition process (step 330) may have a sheath flow of 50 standard cubic centimeters per minute (“sccm”), a carrier flow of 100 sccm, a printing speed of 5-15 mm/s, a platen temperature of 80° C., an ink bath temperature of 30° C., and an ultrasonic energy for aerosolizing the base ink of 310 mA. The curing of the ink may be at 80° C. for 20 minutes.

The discussion above has generally been in the context of the tension being entirely released in step 350 for simplicity. However, such is not required. Instead, step 350 may instead be merely a partial decrease of the tension, rather than a full release, for each of the embodiments discussed above. The decreasing of the tension should be enough to allow the upper surface 104 of the substrate 102 (and the cured ink thereon) to self-organize into a surface having the desired wrinkled profile, but need not be an entire release of the tension. Thus, decreasing of the tension (strain) is intended to encompass both a partial decrease in the tension (strain) and a full release.

The present invention may, of course, be carried out in other ways than those specifically set forth herein without departing from essential characteristics of the invention. The present embodiments are to be considered in all respects as illustrative and not restrictive, and all changes coming within the meaning and equivalency range of the appended claims are intended to be embraced therein.

What is claimed is:

1. A method of forming an electrically conductive layer on a flexible substrate, comprising:
deforming a stretchable substrate so that a first surface thereof is strained in tension by at least 10%;
while the first surface is strained by the at least 10%:
aerosol jet printing an ink onto the first surface of the substrate;
wherein the ink comprises carbon nanotubes;
curing the ink after application to the substrate;
thereafter, decreasing the tension on the substrate so that the substrate relaxes to self-organize into a configuration wherein the first surface of the substrate having cured ink thereon has a wrinkled surface profile.

2. The method of claim 1, wherein the aerosol jet printing comprises aerosol jet printing while the substrate is receiving radiant heat from at least one heat source.

3. The method of claim 1, wherein the aerosol jet printing comprises aerosol jet printing while a second surface of the substrate, which faces opposite the first surface, is spaced from any support at a location directly opposite a print nozzle used for the aerosol jet printing.

4. The method of claim 1, wherein the aerosol jet printing comprises supplying ink from a nozzle directed at the first surface, with no intervening structure between the nozzle and the first surface; and wherein the nozzle is spaced from the first surface during the aerosol jet printing.

5. The method of claim 1, wherein the ink, prior to curing, comprises methanol.

6. The method of claim 1, wherein the decreasing the tension comprises fully releasing the applied tension.

7. The method of claim 1:
wherein, during the aerosol jet printing the ink on the first surface of the substrate, the first surface of the substrate is in tension along a first axis and along a second axis transverse to the first axis;
wherein the decreasing the tension comprises:
decreasing tension along the first axis while maintaining tension along the second axis;
thereafter, decreasing tension along the second axis.

8. The method of claim 1:
wherein, during the aerosol jet printing the ink on the first surface of the substrate, the first surface of the substrate is in tension along a first axis and along a second axis transverse to the first axis;
wherein the decreasing the tension comprises substantially simultaneously decreasing the tension along both the first axis and the second axis.

9. The method of claim 1, further comprising thereafter subjecting the substrate to repeated cycles of mechanical tension and relaxation, with the cured ink maintaining electrical conductivity throughout the mechanical tension and relaxation.

10. The method of claim 1, further comprising thereafter subjecting the substrate to mechanical stress such that the first surface is in tension, and thereafter releasing the mechanical stress, with the cured ink maintaining electrical conductivity throughout the mechanical stressing and releasing.

11. The method of claim 1, wherein the aerosol jet printing and the curing overlap in time.

12. A method of printing a stretchable electrode on a flexible substrate, the method comprising:
deforming an electrode substrate so that a first surface thereof is strained in tension by at least 10%;
while the electrode substrate is deformed so that the first surface thereof is strained in tension by at least 10%:
aerosol jet printing an ink directly onto the first surface of the electrode substrate while the electrode substrate is heated; wherein the ink comprises carbon nanotubes and graphene oxide; wherein a printhead directing the ink to the first surface moves relative to the substrate during the printing;
curing the ink after its application to the substrate;
thereafter:
releasing the tension so that the electrode substrate self-organizes into a configuration wherein the first surface of the electrode substrate having cured ink thereon has a wrinkled surface profile;
discontinuing the heating of the electrode substrate.

13. The method of claim 12, wherein the aerosol jet printing comprises aerosol jet printing while the electrode substrate is receiving radiant heat from at least one heat source.

14. The method of claim 12, wherein the ink, prior to curing, comprises methanol.

15. The method of claim 12, wherein, during the aerosol jet printing the ink on the first surface of the substrate, the first surface of the substrate is in tension along a first axis and along a second axis transverse to the first axis.
